(19) United States
(12) Patent Application Publication
(10) Pub. No.: US 2007/0091578 A1
(43) Pub. Date: Apr. 26, 2007

(54) Circuit board having heat dissipation through holes

(75) Inventors: Chien-Lung Chang, Taipei (TW); Kuo-Hsun Huang, Taipei (TW)

Correspondence Address: BIRCH STEWART KOLASCH & BIRCH, PO BOX 747, FALLS CHURCH, VA, 22040-0747, US

(73) Assignee: ASUSTeK COMPUTER INC.

(21) Appl. No.: 11/546,325

(22) Filed: Oct. 12, 2006

(30) Foreign Application Priority Data
Oct. 20, 2005 (TW) 94136734

(51) Int. Cl. H05K 7/20

(52) U.S. Cl. 361/719

(57) ABSTRACT

A circuit board having heat dissipation through holes, wherein a plurality of through holes are provided in the perimeter of the chip on the circuit board, and heat conduction elements are utilized to connect the heat dissipater and auxiliary heat dissipater provided on two sides of the circuit board. The heat conduction element may be the heat conduction column or heat pipe made of copper or aluminum, and is used to connect the heat dissipater and auxiliary heat dissipater with the shortest distance, thus achieving the speedy transfer of heat generated by the chips and raising the heat dissipation efficiency significantly.

### BACKGROUND

1. Field of Invention

The invention relates a circuit board used for electronic device, and in particular to a circuit board having heat dissipation through holes.

2. Related Art

Nowadays, circuit boards having major electronic components disposed thereon are widely utilized in various electronic devices. For example, the personal computer has various essential chips of central processor unit (CPU), South Bridge, North Bridge provided on its main board. Heat dissipaters are provided in the conventional computer to prevent overheating caused by the high operation speed of CPU. The heat dissipater is made of metal of high heat conductivity and having a plurality of heat sink fins, with its bottom directly in touch with CPU. Heat is absorbed through conduction and then dissipated by means of heat sink fins through convection. In order to raise the efficiency of heat convection and transfer, fans are installed on the heat dissipater to enhance heat convection.

With the rapid progress and development of the computer technology, the operation speed of CPU is ever increasing, thus generating even much more heat. Presently, in addition to CPU, the South Bridge & North Bridge chips on the mainboard, and even the graphic chips on the display card, their operation speeds are likewise getting faster, as such requiring the installation of more dissipaters to reduce and keep their temperature within the normal operation range.

However, with the operation speed of the electronic components on the chips getting increasingly faster more than the heat dissipater's capability can catch up to dissipate the heat generated. In comparison, the heat dissipation capability of the heat dissipater is facing increasing challenge. For the CPU, Northbridge, Southbridge chips on the mainboard, it is much easier to design and install heat dissipater having more powerful heat dissipating capability, due to existence of large gap between the mainboard and the shell. However, for the interface card such as the display card, the gap between the interface cards are rather limited, as such heat is liable to accumulate hot air and not easy to dissipate, thus significantly affecting and reducing its heat dissipation effect. In addition, the size of the shell is gradually miniaturized, and recently with the emergence of micro-systems, thus the heat dissipation function and capability of the dissipater for the chips on the mainboard are facing increasing challenge.

However, due to the limited size of the chips, thus even they are provided with a heat dissipaters having large heat dissipation capability, the heat transferred in this process is rather limited. Therefore, a kind of heat pipe is proposed that is used to transfer the heat energy to the reverse side of the circuit board or to an auxiliary heat dissipater in a distant end, namely, transferring heat to another heat dissipater by means of a heat pipe to raise the heat dissipation efficiency. Yet, in practice, the improvement of heat dissipation efficiency is not quite satisfactory due to the long distance of the heat pipe utilized.

### SUMMARY OF THE INVENTION

In view of the foregoing, the invention provides a heat dissipation circuit board having a plurality of through holes, thus heat is transferred to the auxiliary heat dissipater on the reverse side of the circuit board by the additionally disposed heat conduction elements through the through holes with the shortest distance, thus greatly raising the heat dissipation efficiency.

To achieve the above-mentioned objective, the invention provides a circuit board having heat dissipation through holes, including a circuit board, a heat dissipater, an auxiliary heat dissipater, and a heat conduction element. Various kinds of chips and at least one through hole close to the chip are provided on the circuit board. In addition, heat dissipaters, auxiliary heat dissipaters are disposed on the surfaces of the two opposite sides of the circuit board, and the heat conduction elements are provided in the through holes for connecting the heat dissipater and auxiliary heat dissipater, so that heat may be transferred with the shortest possible distance from the heat dissipater to the auxiliary heat dissipater, thereby raising the heat dissipation efficiency significantly.

In practice, the heat conduction elements may be realized as the heat conduction column made of metal having high heat conduction co-efficiency such as copper and aluminum, and is utilized to transfer heat in cooperation with through hole having diameter larger than 125 mils. In case that the heat conduction element is realized in the heat pipe configuration, the increased heat dissipation efficiency can be achieved without any restriction on the through holes.

Further scope of applicability of the invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The invention will become more fully understood from the detailed description given hereinbelow illustration only, and thus are not limitative of the invention, and wherein:

FIG. 1 is an exploded view of the circuit board having heat dissipation through holes according to the first embodiment of the invention;

FIG. 2 is an assembled view of the circuit board having heat dissipation through holes according to the first embodiment of the invention;

FIG. 3 is a side view of the circuit board having heat dissipation through holes according to the first embodiment of the invention;

FIG. 4 is. an exploded view of the circuit board having heat dissipation through holes according to the second embodiment of the invention;

FIG. 5 is an assembled view of the circuit board having heat dissipation through holes according to the second embodiment of the invention; and

FIG. 6 is a side view of the circuit board having heat dissipation through holes according to the second embodiment of the invention.

### DETAILED DESCRIPTION OF THE INVENTION

The purpose, construction, features, and functions of the invention can be appreciated and understood more thoroughly through the following detailed description with reference to the attached drawings.

The principle of the design and implementation of the circuit board having heat dissipation through holes lies in placing the heat conduction elements directly in the through holes, so that the heat generated by the chips on the circuit board may be transferred from a heat dissipater to an auxiliary heat dissipater with the shortest possible distance. Usually, the heat conduction element is realized as a heat pipe made of copper or aluminum etc having high heat conduction coefficient, and the example of which will be described in detail in the following two preferred embodiments.

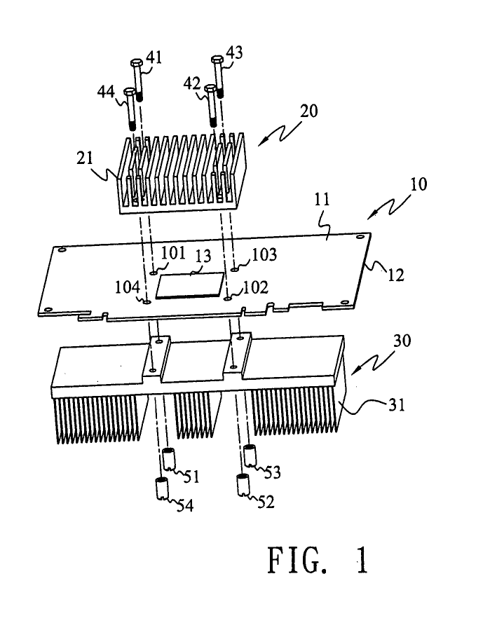

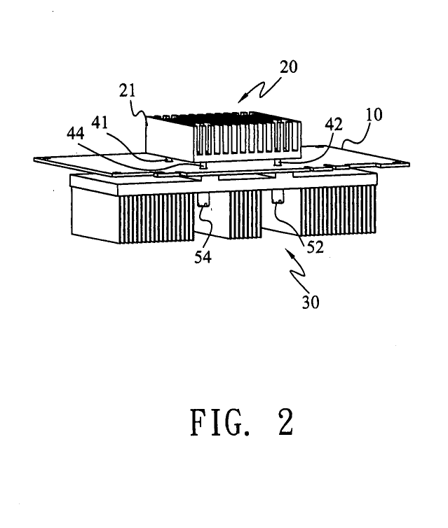

Firstly, refer to FIGS. 1 & 2. FIG. 1 is an exploded view of the circuit board having heat dissipation through holes according to the first embodiment of the invention. FIG. 2 is an assembled view of the circuit board having heat dissipation through holes according to the first embodiment of the invention. As shown in FIG. 1, the circuit board 10 of the invention is composed of a dissipater 20, an auxiliary dissipater 30, and heat conduction columns 41 and 42. Moreover, a first surface 11 and a second surface 12 are provided on each of the two opposite sides of a circuit board 10. Wherein, the first surface 11 is provided with chip 13, and through holes 101, 102 are disposed near the chip 13. The symmetry disposition of the two holes relative to the chip 13 enables the more even transfer of heat.

In the above-mentioned structure, the heat dissipater 20 is provided with a plurality of heat sink fins 21, the number of fins shown in the drawing is for explanatory purpose only, and it is not intended to limit the configuration of the heat dissipater 20 and its related heat sink fins 21. Similarly, the auxiliary heat dissipater 30 is provided with a plurality of heat sink fins 31, likewise, the number of fins shown in the drawing is for explanatory purpose only, and it is not intended to limit the configuration of the auxiliary heat dissipater 30 and its related heat sink fins 31. Heat dissipater 20 is provided on the first surface 11 of the circuit board 10 and above chip 13, with its bottom in contact with chip 13; while the auxiliary heat dissipater 30 is provided on the second surface 12 of the circuit board 10, and the heat conduction columns 41,42 are used to penetrate through the heat dissipater 20, through holes 101 and 12 and reach the auxiliary heat dissipater 30, thus in its bottom portion, the heat conduction columns 41,42 are fixed to the contact communication positions by making use of nuts 51,52. As shown in FIG. 2, the circuit board 10 is further provided with fixing holes 103,104, which are used to provide the auxiliary fixing in cooperation with fixing pieces 43, 44 and nuts 53, 54. In practice, the through holes 101,102 and fixing holes 103,104 are preferred to be disposed respectively on the symmetric four corners of the chips 13 to provide the stability and secure fixing required.

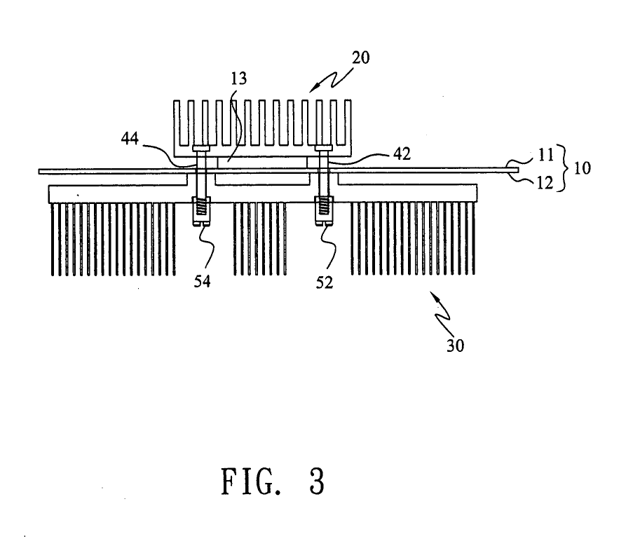

Next, refer to FIG. 3. FIG. 3 is a side view of the circuit board having heat dissipation through holes according to the first embodiment of the invention. As shown in FIG. 3, the heat dissipater 20 is located above and in direct contact with chip 13, thus absorbing the heat energy generated during the operation of chip 13. Then, part of the heat absorbed is dissipated through the heat sink fin 21 disposed above through convection, and the other part of the heat is transferred downward through the heat conduction columns 41 and 42 to the auxiliary heat dissipater 30 located on the second surface 12, then the heat is dissipated through the heat sink fin 31 through heat transfer. To achieve effective heat transfer, the diameter of the heat conduction columns 41 and 42 should be above 125 mils. For the fan fixing hole of the ordinary circuit board, the diameter of the fixing hole is 118±2 mils, that is too small to provide sufficient heat transfer. Thus, correspondingly, the diameter of the through holes 101 and 102 should be at least above 125 mils. As to the shape of the heat conduction columns 41 and 42, in addition to the cylinder shape shown in the drawing, it can be one of the various shapes of cone, square column and circular pedestal etc., to further increase the contact area of the heat conduction columns 41 and 42 with the heat dissipater 20 and the auxiliary heat dissipater 30. Furthermore, the auxiliary heat dissipater 30 does not have to be in direct contact with the second surface 12 of the circuit board 10, the main reason for this is that heat is transferred through the heat conduction columns 41 and 42 rather than through the circuit board 10.

Alternatively, in addition to the two through holes 101 and 102 in cooperation with two heat conduction columns 41 and 42, and the two fixing holes 103 and 104 in cooperation with two fixing pieces 43 and 44, it is possible that all the holes be designed as the through holes with their diameters larger than 125 mils, which can be used to achieve the optimal heat conduction effect in cooperation with the heat conduction column installed. In practice, the installation of at least one through hole in cooperation with a single heat conduction column could achieve the purpose of heat dissipation. Moreover, in addition to the fixing type utilizing nuts 51, 52, 53 and 54 as shown in the drawings, other fixing types may also be utilized such as riveted connection, bonding, gluing and tight engaging.

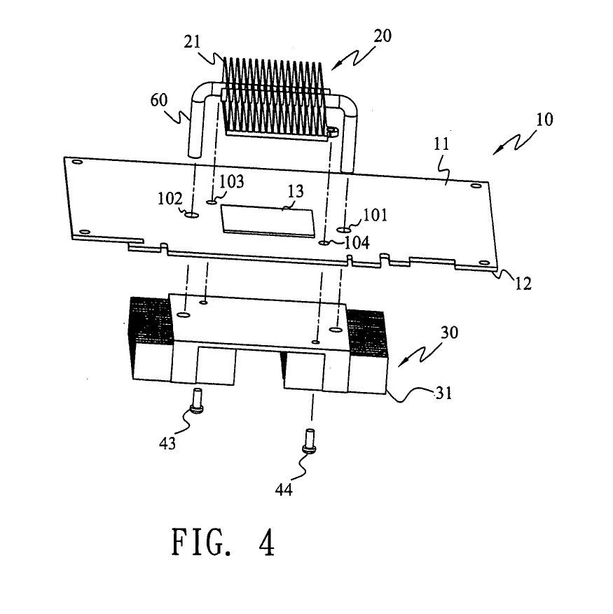

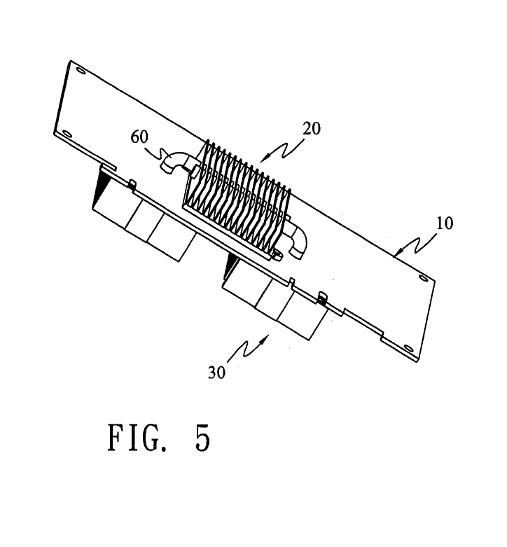

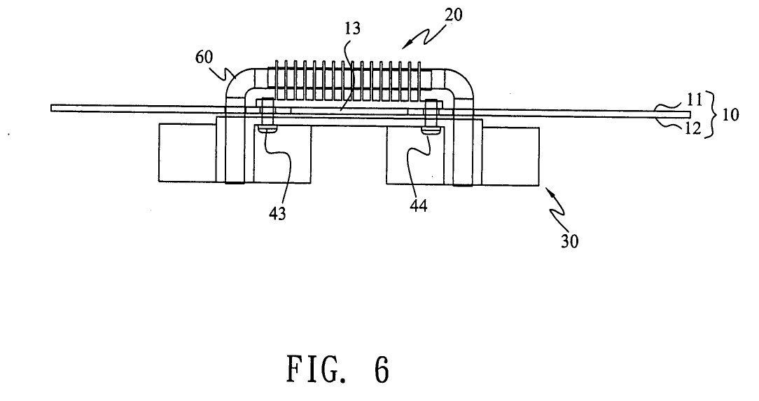

Then, refer to FIGS. 4, 5, and 6 FIG. 4 is an exploded view of the circuit board having heat dissipation through holes according to the second embodiment of the invention. FIG. 5 is an assembled view of the circuit board having heat dissipation through holes according to the second embodiment of the invention. And FIG. 6 is a side view of the circuit board having heat dissipation through holes according to the second embodiment of the invention. As shown in FIGS. 4, 5 and 6, the basic structure, function, and assembly are the same as those shown in FIGS. 1 to 3, and that will not described there for brevity and simplicity. The only difference in the second embodiment is that heat conduction columns are replaced with heat pipes 60, and through holes 101 and 102 are provided on the circuit board 10 for the heat pipe 60 to pass through and connected to the heat dissipater 20 and the auxiliary heat dissipater 30. As such, heat pipe 60 may not be utilized for the fixing purpose as it does in the first embodiment, thus fixing holes 103,104 must be disposed to provide the fixing required in cooperation with the fixing pieces 43 and 44. Similarly, the securing of the fixing pieces 43 and 44 may be realized through various means such as bolt fixing, riveted connection, bonding, gluing, or tight engaging. Likewise, only one of the through holes 101 and 102 allowing the heat pipe 60 to pass through is quite enough to serve the purpose, which can be used to transfer the heat of the heat dissipater 20 to the auxiliary heat dissipater 30. Since heat transfer and not heat conduction is utilized in the heat dissipation through heat pipe 60, therefore, in the second embodiment, the diameters of through holes 101 and 102 are not required to be larger than 125 mils. This is quite different from the manner as adopted in the prior art in dissipating heat generated by the chips on the circuit board, which is not only more costly, but the heat dissipation efficiency is unsatisfactory. The heat conduction column and heat pipe adopted by the invention to conduct or transfer heat directly through the circuit board, thus raising the heat dissipation efficiency significantly.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A circuit board having heat dissipation through holes, comprising:
a circuit board, having a first surface and a second surface opposite to the first surface, the first surface including a chip and at least one through hole near said chip, and a diameter of said through hole being larger than 125 mils;
a heat dissipater, installed on the first surface of said circuit board and located above said chip, to dissipate the heat generated by said chip;
an auxiliary heat dissipater, installed on the second surface of said circuit board; and
a heat conduction column, disposed in the through hole of said circuit board to connect said heat dissipater to said auxiliary heat dissipater for conducting the heat generated by said chip to said auxiliary heat dissipater.

2. The circuit board having heat dissipation through holes of claim 1, wherein two through holes are provided and disposed symmetrically to said chip respectively.

3. The circuit board having heat dissipation through holes of claim 1, wherein four through holes are provided and disposed symmetrically to said chip respectively.

4. The circuit board having heat dissipation through holes of claim 1, wherein said circuit board further comprising at least one fixing hole.

5. The circuit board having heat dissipation through holes of claim 4, further comprising the fixing piece corresponding to said fixing hole to fix said heat dissipater and said auxiliary heat dissipater to said circuit board.

6. The circuit board having heat dissipation through holes of claim 1, further comprising a fixing nut installed on said heat conduction column to fix said heat dissipater and said auxiliary heat dissipater to said circuit board.

7. The circuit board having heat dissipation through holes of claim 1, wherein said heat conduction column is made of metal.

8. The circuit board having heat dissipation through holes of claim 1, wherein said heat dissipater comprises a plurality of heat sink fins.

9. The circuit board having heat dissipation through holes of claim 1, wherein said auxiliary heat dissipater comprises a plurality of heat sink fins.

10. A circuit board having heat dissipation through holes, comprising:
a circuit board, with a first surface and a second surface on two opposite sides, the first surface including a chip and at least one through hole is provided near said chip;
a heat dissipater, installed on the first surface of said circuit and located above said chip to dissipate the heat generated by said chip;
an auxiliary heat dissipater, installed on the second surface of said circuit board; and
a heat pipe, disposed in the through hole of said circuit board to connect said heat dissipater to said auxiliary heat dissipater for transferring the heat generated by said chip to said auxiliary heat dissipater.

11. The circuit board having heat dissipation through holes of claim 10, wherein two through holes are provided and disposed symmetrically to said chip respectively.

12. The circuit board having heat dissipation through holes of claim 10, wherein four through holes are provided and disposed symmetrically to said chip respectively.

13. The circuit board having heat dissipation through holes of claim 10, wherein said circuit board further comprising at least one fixing hole.

14. The circuit board having heat dissipation through holes of claim 13, further comprising the fixing piece corresponding to said fixing hole to fix said heat dissipater and said auxiliary heat dissipater to said circuit board.

15. The circuit board having heat dissipation through holes of claim 10, wherein said heat dissipater comprises a plurality of heat sink fins.

16. The circuit board having heat dissipation through holes of claim 10, wherein said auxiliary heat dissipater comprises a plurality of heat sink fins.
